(19) United States
(12) Patent Application Publication
(10) Pub. No.: US 2025/0338433 A1
(43) Pub. Date: Oct. 30, 2025

(54) COLD PLATE

(71) Applicant: NIDEC CORPORATION, Kyoto (JP)

(72) Inventors: Takehito TAMAOKA, Kyoto (JP); Toshihiko TOKESHI, Kyoto (JP); Hironori ITSUSAKI, Kyoto (JP); Takaya OKUNO, Kyoto (JP)

(21) Appl. No.: 19/184,017

(22) Filed: Apr. 21, 2025

Related U.S. Application Data
(60) Provisional application No. 63/638,510, filed on Apr. 25, 2024.

(30) Foreign Application Priority Data
Aug. 29, 2024 (JP) 2024-147836

(51) Int. Cl. H05K 7/20

(52) U.S. Cl. CPC H05K 7/20254; H05K 7/20263

(57) ABSTRACT

A cold plate includes a bottom wall, a top wall, blades, a side wall, and a mesh portion. The bottom wall includes a lower surface in thermal contact with a heat generating component. The top wall covers an upper surface of the bottom wall. The blades are arranged side by side on the upper surface of the bottom wall and extend linearly. The side wall is located between the bottom wall and the top wall, and defines a refrigerant flow path that surrounds the blades and through which the refrigerant flows. The mesh portion is sheet-shaped, located between the top wall and the blades, and includes a metal portion.

### CROSS-REFERENCE TO RELATED APPLICATIONS

The present application is a Non-Provisional of U.S. Patent Application No. 63/638,510, filed on Apr. 25, 2024, and claims priority under 35 U.S.C. § 119 to Japanese Patent Application No. 2024-147836, filed on Aug. 29, 2024, the entire contents of each application are hereby incorporated herein by reference.

### 1. Field of the Invention

The present disclosure relates to cold plates.

### 2. Background

A conventional cold plate includes a bottom wall, a top wall, a plurality of blades, and a side wall. The bottom wall has a lower surface to be in thermal contact with a heat generating component. The top wall covers an upper surface of the bottom wall. The blades are arranged side by side on the upper surface of the bottom wall and extend linearly. The side wall connects the bottom wall and the top wall, and forms a refrigerant flow path that surrounds the blades and through which refrigerant flows. The cold plate is manufactured by joining the bottom wall and the top wall.

However, in the conventional cold plate, there is a possibility that the blades are deformed and the cooling effect is lowered when the top wall is joined to the bottom wall.

### SUMMARY

An example embodiment of a cold plate of the present disclosure includes a bottom wall, a top wall, blades, a side wall, and a mesh portion. The bottom wall includes a lower surface in thermal contact with a heat generating component. The top wall covers an upper surface of the bottom wall. The blades are arranged side by side on the upper surface of the bottom wall and extend linearly. The side wall is located between the bottom wall and the top wall, and defines a refrigerant flow path that surrounds the blades and through which the refrigerant flows. The mesh portion is a sheet-shaped, located between the top wall and the blades, and includes a metal portion.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a perspective view of a cold plate according to an example embodiment of the present disclosure.

FIG. 2 is an exploded perspective view of a cold plate according to an example embodiment of the present disclosure.

FIG. 3 is a top view of a cold plate according to an example embodiment of the present disclosure.

FIG. 4 is a cross-sectional view taken along line A-A in FIG. 3.

FIG. 5 is a cross-sectional view taken along line B-B in FIG. 3.

FIG. 6 is a top view of a bottom wall of a cold plate according to an example embodiment of the present disclosure.

FIG. 7 is an enlarged perspective view of a portion of a cold plate according to an example embodiment of the present disclosure.

FIG. 8 is a top view illustrating a modification of a bottom wall of a cold plate according to an example embodiment of the present disclosure.

### DETAILED DESCRIPTION

Example embodiments of the present disclosure will be described below with reference to the drawings. In the present application, the opposing direction of a bottom wall 12 and a top wall 13 is referred to as a “vertical direction”. In addition, a direction in which the top wall 13 is located with respect to the bottom wall 12 is referred to as “upward”, and a direction opposite to the direction in which the top wall 13 is located is referred to as “downward”. Moreover, in the present application, a direction orthogonal to the “vertical direction” is referred to as a “horizontal direction”, and the shape and positional relationships of the respective parts will be described.

A direction in which a blade 12a of a cold plate 10 extends is defined as an extending direction (X1-X2), and a direction in which the blades 12a are arranged is defined as an arranging direction (Y1-Y2). In the present example embodiment, the vertical direction (Z1-Z2): is orthogonal to the extending direction (X1-X2) and the arrangement direction (Y1-Y2). However, the vertical direction and the horizontal direction are defined merely for convenience of description, and the orientations of the cold plate 10 according to the present disclosure at the time of manufacture and at the time of use are not limited.

In addition, a “parallel direction” in the present application includes a substantially parallel direction. Moreover, an “orthogonal direction” in the present application includes a substantially orthogonal direction.

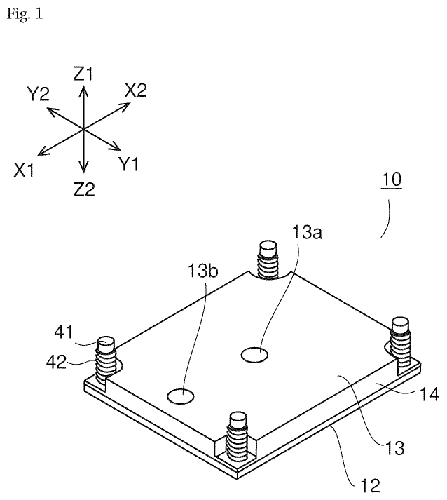

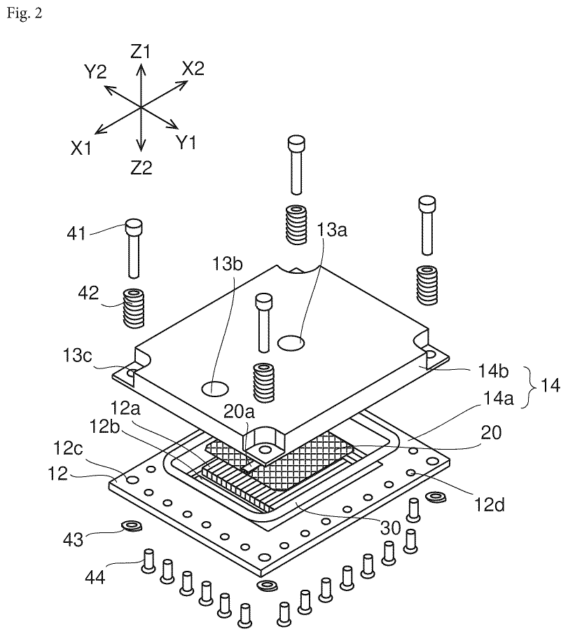

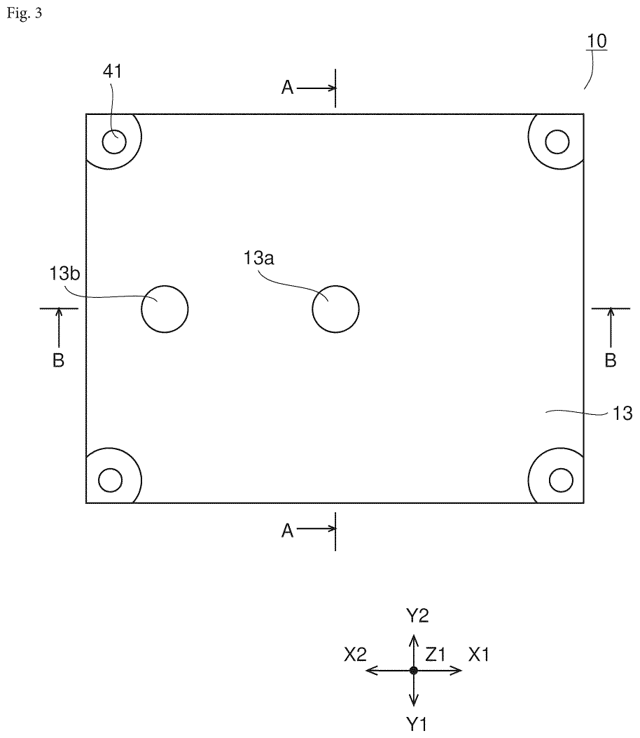

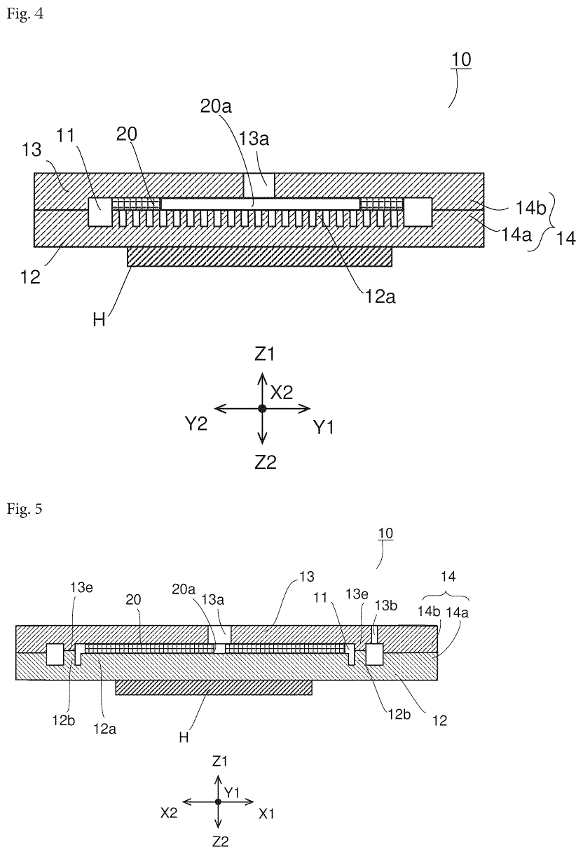

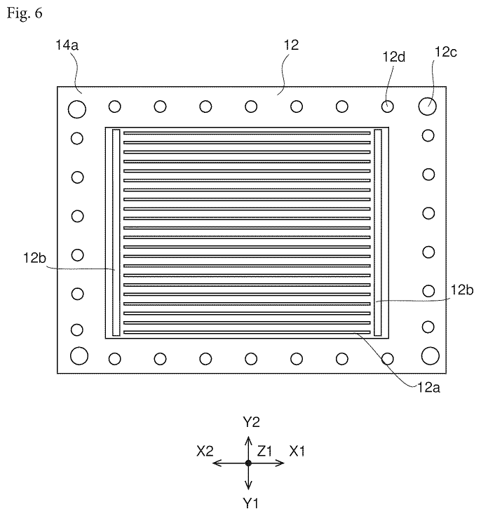

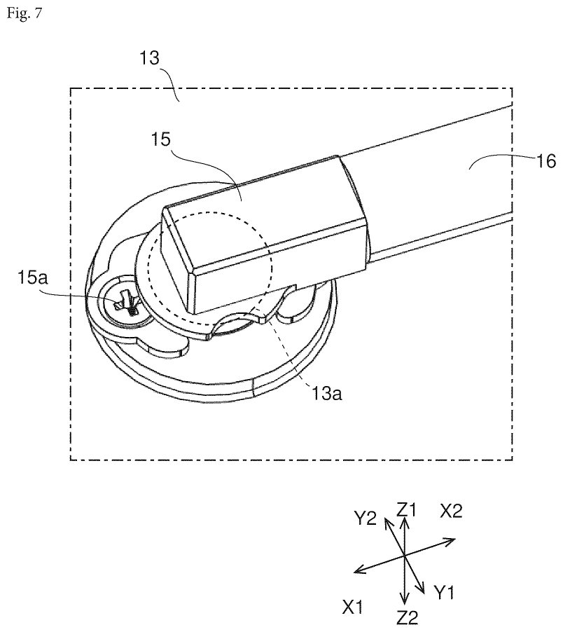

A cold plate according to an exemplary example embodiment of the present disclosure will be described. FIG. 1 is a perspective view of a cold plate 10 according to an example embodiment of the present disclosure, and FIG. 2 is an exploded perspective view of the cold plate 10. FIG. 3 is a top view of the cold plate 10, FIG. 4 is a cross-sectional view taken along line A-A in FIG. 3, and FIG. 5 is a cross-sectional view taken along line B-B in FIG. 2. FIG. 6 is a top view of the bottom wall 12 of the cold plate 10. In FIGS. 1 to 5, an elbow 15 and a refrigerant pipe 16 are omitted.

The cold plate 10 is made of metal having high thermal conductivity such as copper or aluminum, and includes the bottom wall 12, the top wall 13, the side wall 14, a plurality of blades 12a, a plurality of column portions 12b, and a mesh portion 20. In the present example embodiment, the cold plate 10 has a rectangular shape in the top view. That is, the bottom wall 12 and the top wall 13 each have a rectangular plate shape expanding in the horizontal direction in the top view. Note that the bottom wall 12 and the top wall 13 of the present example embodiment each have a quadrangular shape in the top view, but are not limited thereto, and may have, for example, a polygonal shape having a plurality of corners in the top view or a circular shape.

The strength of the cold plate 10 is improved by being made of a copper alloy. Examples of the copper alloy include chromium copper. The strength of the cold plate 10 is improved by being made of chromium copper. As the chromium copper, for example, an alloy obtained by adding 0.3 to 1.7 wt % of chromium to copper is suitably used. When the amount of chromium added to copper is less than 0.3 wt %, the strength of the cold plate 10 decreases. In addition, when the amount of chromium added to copper is more than 1.7 wt %, the hardness increases and the workability of the metal decreases.

The bottom wall 12, the plurality of blades 12a, and the plurality of column portions 12b to be described later are preferably made of chromium copper from the viewpoint of processability and processing accuracy. On the other hand, copper has higher thermal conductivity than chromium copper. Therefore, the cold plate 10 may be formed by combining chromium copper and copper. For example, some blades 12a requiring processability and processing accuracy are made of chromium copper, and the other blades 12a are made of copper. The entire cold plate 10 may be made of only one of copper and chromium copper. When the entire cold plate 10 is made of only copper, thermal conductivity of the cold plate 10 is improved.

The bottom wall 12 has a lower surface to be in thermal contact with a heat generating component H to be cooled, such as a CPU and a GPU (see FIG. 4). The top wall 13 covers an upper surface of the bottom wall 12.

The entire top wall 13 may be made of a metal member, or may be made of a resin member and the outer surface may be made of a metal member by plating. In the case of plating, it is more preferable to use the same metal member as that of the bottom wall 12. When at least a part of the top wall 13 is made of a metal member, the strength is improved. When the top wall 13 is made of the same metal member as that of the bottom wall 12, it is possible to reduce generation of a potential difference between the bottom wall 12 and the top wall 13 when the refrigerant flows through the cold plate 10. Therefore, corrosion of the top wall 13 can be suppressed.

The top wall 13 has a protruding portion 13e protruding from the lower surface (see FIG. 5). The protruding portion 13e is in contact with the column portion 12b described later in the vertical direction (Z1-Z2). In the present example embodiment, the protruding portion 13e extends in the arrangement direction (Y1-Y2). The protruding portion 13e and the side wall 14 face each other in the extending direction (X1-X2) and the arrangement direction (Y1-Y2) with a gap interposed therebetween. Since the protruding portion 13e is provided, the strength of the top wall 13 is further improved.

The side wall 14 is located between the bottom wall 12 and the top wall 13, and forms a refrigerant flow path 11 that surrounds the blades 12a and through which the refrigerant flows. In the present example embodiment, the side wall 14 has a rectangular annular shape in the top view. The side wall 14 connects peripheral edges of the bottom wall 12 and the top wall 13.

The side wall 14 includes a first side wall portion 14a protruding upward (Z1) from the peripheral edge of the bottom wall 12 and a second side wall portion 14b protruding downward (Z2) from the peripheral edge of the top wall 13. The upper surface of the first side wall portion 14a and the lower surface of the second side wall portion 14b are joined via a seal member 30. The seal member 30 is annularly formed to surround the refrigerant flow path 11. As the seal member 30, for example, a rubber O-ring, a rubber packing, or the like is suitably used. As a result, refrigerant leakage around the refrigerant flow path 11 can be suppressed.

In the present example embodiment, the side wall 14 is configured of the first side wall portion 14a and the second side wall portion 14b, but may be configured by only one of them. That is, the upper surface of the first side wall portion 14a may be joined to the lower surface of the top wall 13 without the second side wall portion 14b, or the lower surface of the second side wall portion 14b may be joined to the upper surface of the bottom wall 12 without the first side wall portion 14a.

The first side wall portion 14a has a first screw hole 12c and a second screw hole 12d penetrating in the vertical direction (Z1-Z2). First screw holes 12c are located at four locations at corners of the bottom wall 12. A plurality of second screw holes 12d is located to surround the refrigerant flow path 11.

The second side wall portion 14b has a third screw hole 13c penetrating in the vertical direction (Z1-22) and a fourth screw hole (not illustrated) formed to be recessed upward Z1. The third screw holes 13c are located at four locations at corners of the top wall 13. The plurality of fourth screw holes is located to surround the refrigerant flow path 11.

The second screw hole 12d and the fourth screw hole (not illustrated) are aligned and screwed with a screw 44. As a result, the bottom wall 12 and the top wall 13 are fixed. As the screw 44, for example, a tapping screw is used. When the top wall 13 and the second side wall portion 14b are made of a metal member, the fourth screw hole (not shown) may be threaded in advance. An adhesive may be applied between the screw 44 and the fourth screw hole. As a result, the fixing strength between the bottom wall 12 and the top wall 13 is improved.

In addition, the first screw hole 12c and the third screw hole 13c are made to coincide with each other, and are screwed to the actual machine having the heat generating component H with the screw 41 and the stopper 43 via the spring 42. As a result, the cold plate 10 can be brought into contact with the heat generating component H with a predetermined pressing force by the elastic force of the spring 42.

The refrigerant flow path 11 is formed in an internal space surrounded by the bottom wall 12, the top wall 13, and the side wall 14. The cold plate 10 includes an inlet 13a through which the refrigerant flows into the refrigerant flow path 11 and an outlet 13b through which the refrigerant flows out of the refrigerant flow path 11.

The inlet 13a is located on one end side of the refrigerant flow path 11. The outlet 13b is located on the other end side of the refrigerant flow path 11. The refrigerant flowing into the refrigerant flow path 11 through the inlet 13a flows out of the refrigerant flow path 11 through the outlet 13b. In the present example embodiment, the inlet 13a and the outlet 13b are circular, and are formed penetrating the top wall 13 in the vertical direction. The refrigerant is liquid, and for example, an antifreeze such as an ethylene glycol aqueous solution or a propylene glycol aqueous solution, pure water, or the like is used.

The plurality of blades 12a is arranged side by side on the upper surface of the bottom wall 12 and linearly extend in the extending direction (X1-X2). In the present example embodiment, the blade 12a is the same member as the bottom wall 12. The blades 12a are formed by, for example, cutting a plurality of linear grooves extending in the extending direction (X1-X2) on the upper surface of the bottom wall 12. As a result, thermal conductivity from the bottom wall 12 to the refrigerant flowing through the refrigerant flow path 11 via the blades 12a is improved. The blade 12a may be formed of a member different from the bottom wall 12. For example, the blade 12a may be formed in a plate-shaped base member, and the bottom wall 12 and the base member may be welded.

The plurality of column portions 12b protrudes from the upper surface of the bottom wall 12 and face each other in the extending direction (X1-X2) of the blades 12a with the blades 12a interposed therebetween, inside the side wall 14. In the present example embodiment, the upper end of the column portion 12b is positioned above (Z1) the upper end of the blade 12a. The width of the column portion 12b in the extending direction (X1-X2) and the width of the column portion 12b in the arrangement direction (Y1-Y2) are larger than the width of the blade 12a in the arrangement direction (Y1-Y2).

In the present example embodiment, the column portion 12b extends in the arrangement direction (Y1-Y2) of the blades 12a. The column portion 12b faces the blades 12a in the extending direction (X1-X2) with a gap interposed therebetween. An end of the column portion 12b in the arrangement direction (Y1-Y2) faces the side wall 14 extending in the extending direction (X1-X2) in the arrangement direction (Y1-Y2) with a gap interposed therebetween at a corner of the side wall 14. The end of the column portion 12b in the arrangement direction (Y1-Y2) faces the side wall 14 extending in the arrangement direction (Y1-Y2) in the extending direction (X1-X2) with a gap interposed therebetween. The refrigerant flows through the gap around the column portion 12b.

Since the column portion 12b is provided, the strength of the bottom wall 12 is improved and bending of the bottom wall 12 can be suppressed. As a result, deformation of the blade 12a can be reduced. In addition, the column portion 12b extends in the arrangement direction (Y1-Y2) of the blades 12a, so that it is possible to further suppress bending of the bottom wall 12 in the arrangement direction (Y1-Y2).

When the top wall 13 is joined to the bottom wall 12, the column portions 12b support the top wall 13. As a result, it is possible to prevent the top wall 13 from pressing the blade 12a via the mesh portion 20 and to prevent deformation of the blade 12a. In addition, the upper end of the column portion 12b is located above (Z1) the upper end of the blade 12a, and the force applied to the blade 12a from the top wall 13 via the mesh portion 20 can be reduced. As a result, deformation of the blade 12a during manufacturing can be suppressed. As a result, it is possible to suppress degradation of the cooling effect due to deformation of the blade 12a. The upper end of the column portion 12b may be located at the same position as the upper end of the blade 12a.

In addition, since the protruding portion 13e in contact with the column portion 12b is provided on the top wall 13, the strength of the top wall 13 is improved and the deflection of the top wall 13 can be suppressed. Thus, the force applied to the blade 12a from the top wall 13 via the mesh portion 20 can be further reduced. Further, since the column portions 12b and the protruding portions 13e are provided, the positioning of the mesh portion 20 with respect to the bottom wall 12 and the positioning of the mesh portion 20 with respect to the top wall 13 are facilitated.

The column portions 12b are located to face each other in the extending direction (X1-X2) of the blades 12a with the blades 12a interposed therebetween, and the cutting blade is inserted in the arrangement direction (Y1-Y2) when the blades 12a are formed by cutting. As a result, the cutting blade is less likely to come into contact with the column portion 12b. Accordingly, the blades 12a aligned in the arrangement direction (Y1-Y2) can be formed with high definition, thereby improving the efficiency of manufacturing the cold plate 10.

The mesh portion 20 has a sheet shape and is located between the top wall 13 and the blade 12a. The mesh portion 20 is located between a pair of column portions 12b.

The mesh portion 20 is made of a metal member, and is formed by interweaving a metal wire-shaped member, for example. The mesh portion 20 is preferably made of the same material as the metal member constituting the top wall 13 or the bottom wall 12. By disposing the mesh portion 20 made of a metal member, the strength of the top wall 13 is improved, and deformation of the top wall 13 can be suppressed. Moreover, heat conductivity from the refrigerant flowing through the refrigerant flow path 11 to the top wall 13 is improved via the mesh portion 20. As a result, a temperature rise of the heat generating component H can be further suppressed. In addition, the mesh portion 20 made of a metal member is hardly deformed by heat, and it is possible to suppress deterioration of the cooling effect by closing the refrigerant flow path 11.

In the present example embodiment, the mesh portion 20 is sandwiched between the top wall 13 and the blade 12a in the vertical direction (Z1-22), and is in contact with the top wall 13 and the blade 12a. As a result, the top wall 13, the mesh portion 20, and the blade 12a are integrated to further improve the strength of the cold plate 10.

The mesh portion 20 is fixed to the top wall 13 via a welded portion or a brazed portion. As a result, the strength of the top wall 13 is further improved. As a method of fixing the mesh portion 20, specifically, a brazing material is located between the top wall 13 and the mesh portion 20, and the cold plate 10 is fired in a heating furnace in a state where the top wall 13 and the bottom wall 12 are joined. Thus, the top wall 13 and the mesh portion 20 can be easily fixed.

At this time, a part of the brazing material melted at the time of heating flows into the mesh portion 20. The brazing material tends to stay in the mesh portion 20 due to a capillary phenomenon, and hardly flows into the gap between the blades 12a. Therefore, it is possible to reduce the possibility that the flow path between the blades 12a is blocked by the brazing material. Accordingly, reduction in cooling effect of the cold plate 10 can be suppressed.

The mesh opening of the mesh portion 20 is preferably smaller than the gap between the blades 12a adjacent to each other in the arrangement direction (Y1-Y2). By making the mesh opening of the mesh portion 20 smaller than the gap between the blades 12a, the brazing material melted by heat is likely to remain in the mesh portion due to the capillary phenomenon. As a result, it is possible to further suppress the brazing material from flowing into the flow path between the blades 12a. The “mesh opening” is a dimension of a gap portion of the mesh, and means the shortest distance among the gap distances between two metal wire-shaped members adjacent to each other in the mesh portion 20 and extending parallel to a predetermined direction.

It is preferable that a plurality of the mesh portions 20 are arranged in an overlapping manner in the vertical direction (Z1-Z2 direction). By overlapping the plurality of mesh portions 20, the mesh portion 20 serves as a cushioning material, and the blade 12a is protected. As a result, it is possible to reduce deformation of the blade 12a when the bottom wall 12 and the top wall 13 are joined. In addition, by overlapping the plurality of mesh portions 20, the brazing material melted by heat is more likely to remain on the mesh portions due to the capillary phenomenon.

In the top wall 13, at least a region opposing the blade in the vertical direction (Z1-Z2) is preferably made of a metal member. Thus, the mesh portion 20 and the top wall 13 can be more firmly fixed. In addition, the heat conductivity from the refrigerant flowing through the refrigerant flow path 11 to the top wall 13 is further improved.

The mesh portion 20 has a flow hole 20a penetrating in the vertical direction (Z1-Z2). In the present example embodiment, the flow hole 20a extends in the arrangement direction (Y1-Y2). The flow hole 20a faces the inlet 13a in the vertical direction (Z1-Z2). As a result, the refrigerant smoothly flows into the refrigerant flow path 11 via the inlet 13a and the flow hole 20a.

FIG. 7 is an enlarged perspective view of a part of the cold plate 10. The cold plate 10 further includes the elbow 15 and the refrigerant pipe 16. The elbow 15 is located on the upper surface of the top wall 13, and is connected to the refrigerant inlet 13a or outlet 13b of the refrigerant flow path 11. The refrigerant pipe 16 is connected to the elbow 15 in the horizontal direction by welding or brazing, and extends along the upper surface of the top wall 13.

The elbow 15 may be connected to both the inlet 13a and the outlet 13b, or may be connected to only one of them. The elbow 15 has at least a surface made of a metal member having high thermal conductivity such as copper or aluminum. That is, the elbow 15 may be entirely made of a metal member, or may be made of a resin member and have a surface made of a metal member by plating. By performing the plating process, the strength can be improved as compared with the case where only the resin member is used. As a result, the strength of the piping member around the inlet 13a and the outlet 13b can be improved, and the refrigerant leakage around the inlet 13a and the outlet 13b can be suppressed.

The strength of the elbow 15 is improved by being made of a copper alloy. The elbow 15 may be entirely made of a copper alloy, or may be made of a resin member and have a surface made of a copper alloy by plating. Examples of the copper alloy include chromium copper. The strength of the elbow 15 is improved by being made of chromium copper. As the chromium copper, for example, an alloy obtained by adding 0.3 to 1.7 wt % of chromium to copper is suitably used. When the amount of chromium added to copper is less than 0.3 wt %, the strength of the elbow 15 decreases. In addition, when the amount of chromium added to copper is more than 1.7 wt %, the hardness increases and the workability of the metal decreases.

Examples of the plating process on the resin member include a degreasing step, an etching step, a neutralization step, a catalyst/accelerator step, and an electroless plating step.

The metal member constituting the elbow 15 is preferably made of the same material as the metal member constituting the top wall 13 or the bottom wall 12. This configuration reduces generation of a potential difference between the elbow 15 and the top wall 13 or between the elbow 15 and the bottom wall 12 when the refrigerant flows through the cold plate 10. Therefore, it is possible to suppress corrosion of the elbow 15, the top wall 13, and the bottom wall 12.

In the elbow 15, the portion in contact with the refrigerant including the inside through which the refrigerant flows is made of a resin member, so that corrosion can be suppressed while reducing the weight of the elbow 15. As a result, refrigerant leakage around the inlet 13a and the outlet 13b can be further suppressed.

The elbow 15 changes the circulation direction of the refrigerant from the vertical direction (Z1-Z2) to the horizontal direction. The elbow 15 is screwed to the top wall 13 via a plurality of screws 15a, for example. Although not illustrated, a seal member such as a rubber O-ring or a rubber packing is preferably located between the elbow 15 and the top wall 13. As a result, refrigerant leakage around the inlet 13a and the outlet 13b can be further suppressed.

Since the elbow 15 is provided, the refrigerant pipe 16 can be easily connected to the inlet 13a and the outlet 13b. Moreover, by disposing the refrigerant pipe 16 along the upper surface of the top wall 13, the cold plate 10 can be downsized in the vertical direction (Z1-Z2). The elbow 15 is fixed to the top wall 13 by being rotated about the vertical direction (Z1-Z2), so that the extending direction of the refrigerant pipe 16 can be freely changed in the horizontal direction.

The refrigerant pipe 16 is connected to a pump (not illustrated) that circulates the refrigerant. When the pump is driven, the refrigerant circulates through the refrigerant flow path 11. The heat of the heat generating component H is transferred to the bottom wall 12 of the cold plate 10. The heat transferred to the bottom wall 12 is transferred to the refrigerant flowing through the refrigerant flow path 11. The refrigerant radiates heat via a radiator (not illustrated). As a result, a temperature rise of the heat generating component H can be suppressed.

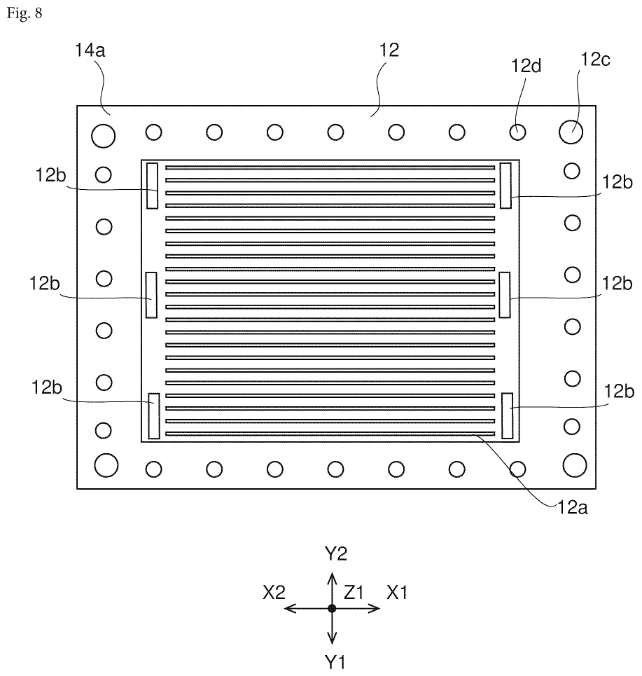

FIG. 8 is a top view showing a modification of the bottom wall 12 of the cold plate 10. The column portion 12b may be divided into a plurality of portions in the extending direction (X1-X2). At this time, at the corners of the side wall 14, at least some of the column portions 12b preferably face the side wall 14 extending in the extending direction (X1-X2) in the arrangement direction (Y1-Y2) with a gap interposed therebetween, and face the side wall 14 extending in the arrangement direction (Y1-Y2) in the extending direction (X1-X2) with a gap interposed therebetween. As a result, it is possible to particularly prevent the blades 12a from being deformed around the corners of the side wall 14.

The above example embodiment is merely an example of the present disclosure. The configuration of the example embodiment may be appropriately changed without departing from the technical idea of the present disclosure. In addition, the example embodiment may be implemented in combination within a feasible range. For example, the column portion 12b is brought into contact with the protruding portion 13e in the vertical direction (Z1-Z2), but the protruding portion 13e may be omitted.

As described above, a cold plate (10) according to an aspect of the present disclosure includes: a bottom wall (12) including a lower surface in thermal contact with a heat generating component (H); a top wall (13) that covers an upper surface of the bottom wall; blades (12a) arranged side by side on the upper surface of the bottom wall and extending linearly; a side wall (14) arranged between the bottom wall and the top wall and defining a refrigerant flow path (11) that surrounds the blades and through which a refrigerant flows; and a mesh portion (20) in a sheet shape arranged between the top wall and the blades, the mesh portion being defined by a metal portion (first configuration).

In the first configuration, at least a region of the top wall opposing the blades in the vertical direction (Z1-Z2) may be defined by a metal portion (second configuration).

In the first or second configuration, the mesh portion may be fixed to the top wall via a welded portion or a brazed portion (third configuration).

In any one of the first to third configurations, the mesh portion may include a mesh opening smaller than a gap between the adjacent blades (fourth configuration).

In any one of the first to fourth configurations, a plurality of the mesh portions may be arranged in an overlapping manner in the vertical direction (fifth configuration).

In any one of the first to fifth configurations, the mesh portion may be in contact with the top wall and the blades (sixth configuration).

In any one of the first to sixth configurations, a plurality of column portions (12b) may be further included, the column portions protruding from the upper surface of the bottom wall and opposing each other in the extending direction of the blades with the blades interposed therebetween inside the side wall, and an upper end of the column portion may be located at the same position as an upper end of the blade or above the upper end of the blade (seventh configuration).

In the seventh configuration, the column portion and the blades may oppose each other in the extending direction with a gap interposed therebetween (eighth configuration).

In any one of the first to eighth configurations, an elbow (15) located on an upper surface of the top wall and connected to an inlet (13a) or an outlet (13b) of the refrigerant in the refrigerant flow path may be further provided, and at least a surface of the elbow may be made of a metal member (ninth configuration).

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cold plate comprising:
a bottom wall including a lower surface in thermal contact with a heat generating component;
a top wall that covers an upper surface of the bottom wall;
a plurality of blades arranged side by side on the upper surface of the bottom wall and extending linearly;
a side wall between the bottom wall and the top wall, and defining a refrigerant flow path that surrounds the plurality of blades and through which a refrigerant flows; and
a mesh portion that is sheet-shaped, located between the top wall and the blades, and includes a metal portion.

2. The cold plate according to claim 1, wherein at least a region of the top wall that vertically opposes the blades includes another metal portion.

3. The cold plate according to claim 1, wherein the mesh portion is fixed to the top wall via a welded portion or a brazed portion.

4. The cold plate according to claim 3, wherein a mesh opening of the mesh portion is smaller than a gap between ones of the blades adjacent to each other.

5. The cold plate according to claim 4, wherein a plurality of the mesh portions is vertically located in an overlapping manner.

6. The cold plate according to claim 5, wherein the mesh portion is in contact with the top wall and the blades.

7. The cold plate according to claim 1, further comprising:
column portions protruding from the upper surface of the bottom wall and opposing each other in an extending direction of the blades with the blades interposed between the column portions inside the side wall; wherein
an upper end of each of the column portions is located at a same position as or above an upper end of each of the blades.

8. The cold plate according to claim 7, wherein the column portions and the blades oppose each other in the extending direction over a gap.

9. The cold plate according to claim 1, further comprising:
an elbow located on an upper surface of the top wall and connected to an inlet or an outlet of the refrigerant in the refrigerant flow path; wherein
at least a surface of the elbow includes another metal portion.
